(19) United States
(12) Patent Application Publication
(10) Pub. No.: US 2026/0075914 A1
(43) Pub. Date: Mar. 12, 2026

(54) SEMICONDUCTOR DEVICE AND METHOD OF MANUFACTURING SEMICONDUCTOR DEVICE

(71) Applicant: SUMITOMO ELECTRIC DEVICE INNOVATIONS, INC., Kanagawa (JP)

(72) Inventor: Hiroyuki OGURI, Kanagawa (JP)

(21) Appl. No.: 19/316,280

(22) Filed: Sep. 2, 2025

(30) Foreign Application Priority Data
Sep. 12, 2024 (JP) 2024-158434

(51) Int. Cl. H10D 64/23; H10D 30/01; H10D 30/47; H10D 64/01

(52) U.S. Cl. CPC H10D 64/254; H10D 30/015; H10D 30/471; H10D 64/01

(57) ABSTRACT

A semiconductor device includes a substrate having a first surface and a second surface; a first nitride semiconductor layer having a third surface and a fourth surface, the first nitride semiconductor layer having a recess formed in the fourth surface; a second nitride semiconductor layer provided in the recess; and a first metal layer. An opening is formed in the substrate and the first nitride semiconductor layer.

The opening penetrates the substrate and the first nitride semiconductor layer, reaches the second nitride semiconductor layer, and has a bottom surface in the second nitride semiconductor layer. The first metal layer covers the first surface and an inner wall surface of the opening and is in contact with the second nitride semiconductor layer at the bottom surface of the opening. The second nitride semiconductor layer contains impurity atoms at a concentration of 1.0×10¹⁸ cm⁻³ or higher.

### CROSS-REFERENCE TO RELATED APPLICATIONS

This application is based on and claims priority to Japanese Patent Application No. 2024-158434, filed on Sep. 12, 2024, the entire contents of which are incorporated herein by reference.

### TECHNICAL FIELD

The present disclosure relates to a semiconductor device and a method of manufacturing the semiconductor device.

### BACKGROUND

A semiconductor device in which a metal layer in ohmic contact with a semiconductor layer, containing carriers at a high concentration, is formed as an etching stopper on the semiconductor layer is known. In the semiconductor device, a through hole reaching the etching stopper is formed in the semiconductor layer, and an electrode in contact with the etching stopper is formed in the through hole. See Japanese Laid-open Patent Publication No. 2011-077434, Japanese Laid-open Patent Publication No. 2020-017647, and Japanese Laid-open Patent Publication No. 2024-092747, for example.

### SUMMARY

According to an embodiment of the present disclosure, a semiconductor device includes a substrate having a first surface and a second surface opposite to the first surface; a first nitride semiconductor layer having a third surface in contact with the second surface, and a fourth surface opposite to the third surface, the first nitride semiconductor layer having a recess formed in the fourth surface; a second nitride semiconductor layer provided in the recess; and a first metal layer. An opening is formed in the substrate and the first nitride semiconductor layer. The opening penetrates the substrate and the first nitride semiconductor layer, reaches the second nitride semiconductor layer, and has a bottom surface in the second nitride semiconductor layer. The first metal layer covers the first surface and an inner wall surface of the opening and is in contact with the second nitride semiconductor layer at the bottom surface of the opening. The second nitride semiconductor layer contains impurity atoms at a concentration of 1.0×10¹⁸ cm⁻³ or higher.

### BRIEF DESCRIPTION OF THE DRAWINGS

FIG. 1 is a diagram illustrating a layout of gate electrodes and drain interconnects of a semiconductor device according to a first embodiment;

FIG. 2 is a cross-sectional view illustrating the semiconductor device according to the first embodiment;

FIG. 3 is a diagram illustrating a band structure of a semiconductor layer (regrown layer);

FIG. 4 is a cross-sectional view (part 1) illustrating a first example of a method of manufacturing the semiconductor device according to the first embodiment;

FIG. 5 is a cross-sectional view (part 2) illustrating the first example of the method of manufacturing the semiconductor device according to the first embodiment;

FIG. 6 is a cross-sectional view (part 3) illustrating the first example of the method of manufacturing the semiconductor device according to the first embodiment;

FIG. 7 is a cross-sectional view (part 4) illustrating the first example of the method of manufacturing the semiconductor device according to the first embodiment;

FIG. 8 is a cross-sectional view (part 5) illustrating the first example of the method of manufacturing the semiconductor device according to the first embodiment;

FIG. 9 is a cross-sectional view (part 6) illustrating the first example of the method of manufacturing the semiconductor device according to the first embodiment;

FIG. 10 is a cross-sectional view (part 7) illustrating the first example of the method of manufacturing the semiconductor device according to the first embodiment;

FIG. 11 is a cross-sectional view (part 8) illustrating the first example of the method of manufacturing the semiconductor device according to the first embodiment;

FIG. 12 is a cross-sectional view (part 9) illustrating the first example of the method of manufacturing the semiconductor device according to the first embodiment;

FIG. 13 is a cross-sectional view (part 10) illustrating the first example of the method of manufacturing the semiconductor device according to the first embodiment;

FIG. 14 is a cross-sectional view (part 1) illustrating a second example of the method of manufacturing the semiconductor device according to the first embodiment;

FIG. 15 is a cross-sectional view (part 2) illustrating the second example of the method of manufacturing the semiconductor device according to the first embodiment;

FIG. 16 is a cross-sectional view illustrating a semiconductor device according to a reference example;

FIG. 17 is a cross-sectional view (part 1) illustrating a method of manufacturing the semiconductor device according to the reference example;

FIG. 18 is a cross-sectional view (part 2) illustrating the method of manufacturing the semiconductor device according to the reference example;

FIG. 19 is a cross-sectional view (part 3) illustrating the method of manufacturing the semiconductor device according to the reference example;

FIG. 20 is a cross-sectional view (part 4) illustrating the method of manufacturing the semiconductor device according to the reference example;

FIG. 21 is a cross-sectional view (part 5) illustrating the method of manufacturing the semiconductor device according to the reference example;

FIG. 22 is a cross-sectional view (part 6) illustrating the method of manufacturing the semiconductor device according to the reference example;

FIG. 23 is a cross-sectional view (part 7) illustrating the method of manufacturing the semiconductor device according to the reference example;

FIG. 24 is a diagram illustrating a layout of gate electrodes, source interconnects, and drain interconnects of a semiconductor device according to a second embodiment; and

FIG. 25 is a cross-sectional view illustrating the semiconductor device according to the second embodiment.

### DETAILED DESCRIPTION

In the related-art semiconductor device, there is a possibility that the contact resistance between the electrode and the semiconductor layer increases, thereby resulting in a decrease in yield.

It is an object of an embodiment of the present disclosure to provide a semiconductor device and a method of manufacturing the semiconductor device that can improve yield.

According to an embodiment of the present disclosure, yield can be improved.

### Description of Embodiments of the Present Disclosure

First, embodiments of the present disclosure will be listed and described.

[1] A semiconductor device according to one aspect of the present disclosure includes a substrate having a first surface and a second surface opposite to the first surface; a first nitride semiconductor layer having a third surface in contact with the second surface, and a fourth surface opposite to the third surface, the first nitride semiconductor layer having a recess formed in the fourth surface; a second nitride semiconductor layer provided in the recess; and a first metal layer, wherein an opening is formed in the substrate and the first nitride semiconductor layer, the opening penetrating the substrate and the first nitride semiconductor layer, reaching the second nitride semiconductor layer, and having a bottom surface in the second nitride semiconductor layer, the first metal layer covers the first surface and an inner wall surface of the opening and is in contact with the second nitride semiconductor layer at the bottom surface of the opening, and the second nitride semiconductor layer contains impurity atoms at a concentration of 1.0×10¹⁸ cm⁻⁻³ or higher.

The second nitride semiconductor layer is formed in the recess that is formed in the fourth surface of the first nitride semiconductor layer, and the second nitride semiconductor layer contains impurity atoms at a concentration of 1.0×10¹⁸ cm⁻³ or higher. Further, the first metal layer is in contact with the second nitride semiconductor layer at the bottom surface of the opening, and the first metal layer and the second nitride semiconductor layer are in ohmic contact with each other. Thus, the electrical resistance between the first nitride semiconductor layer and the first metal layer is low. Accordingly, as compared to when another metal layer is present in a current path between the first metal layer and the first nitride semiconductor layer, the stability of the electrical resistance between the first metal layer and the first nitride semiconductor layer is good, and yield can be improved.

[2] In [1], a thickness of the second nitride semiconductor layer may be 20 nm or more and 1,000 nm or less. When the thickness of the second nitride semiconductor layer is 20 nm or more, etching of the first nitride semiconductor layer and the second nitride semiconductor layer is easily stopped before the opening penetrates the second nitride semiconductor layer. When the thickness of the second nitride semiconductor layer is 1,000 nm or less, the time required for the formation of the recess and the formation of the second nitride semiconductor layer is easily reduced.

[3] In [1] or [2], the second nitride semiconductor layer may be a gallium nitride layer. In this case, a low electrical resistance is easily obtained for the second nitride semiconductor layer.

[4] In any one of [1] to [3], a Fermi level may be higher than energy at a bottom of a conduction band in the second nitride semiconductor layer. In this case, an ohmic contact is easily obtained between the second nitride semiconductor layer and the first metal layer.

[5] In any one of [1] to [4], a carrier density of the second nitride semiconductor layer may be higher than a carrier density of the first nitride semiconductor layer. In this case, the electrical resistance of the second nitride semiconductor layer is easily reduced.

[6] In any one of [1] to [5], the semiconductor device may further include a second metal layer provided on the second nitride semiconductor layer, wherein the second nitride semiconductor layer may be located between the first metal layer and the second metal layer. In this case, the second metal layer can be used to perform a characteristic inspection.

[7] A method of manufacturing a semiconductor device according to another aspect of the present disclosure includes forming a first nitride semiconductor layer on a substrate having a first surface and a second surface opposite to the first surface, the first nitride semiconductor layer having a third surface in contact with the second surface, and a fourth surface opposite to the third surface; forming a recess in the fourth surface; forming a second nitride semiconductor layer in the recess; forming an opening in the substrate and the first nitride semiconductor layer, the opening penetrating the substrate and the first nitride semiconductor layer, reaching the second nitride semiconductor layer, and having a bottom surface in the second nitride semiconductor layer; and forming a first metal layer covering the first surface and an inner wall surface of the opening and in contact with the second nitride semiconductor layer at the bottom surface of the recess, wherein the second nitride semiconductor layer contains impurity atoms at a concentration of 1.0×10¹⁸ cm⁻³ or higher.

The recess is formed in the fourth surface of the first nitride semiconductor layer, the second nitride semiconductor layer is formed in the recess, and the second nitride semiconductor layer contains impurity atoms at a concentration of 1.0×10¹⁸ cm⁻³ or higher. Further, the first metal layer is in contact with the second nitride semiconductor layer at the bottom surface of the opening, and the first metal layer and the second nitride semiconductor layer are in ohmic contact with each other. Thus, the electrical resistance between the first nitride semiconductor layer and the first metal layer is low. Accordingly, as compared to when another metal layer is present in a current path between the first metal layer and the first nitride semiconductor layer, the stability of the electrical resistance between the first metal layer and the first nitride semiconductor layer is good, and thus yield can be improved.

### DETAILS OF EMBODIMENTS OF PRESENT DISCLOSURE

Hereinafter, embodiments of the present disclosure will be described in detail, but the present disclosure is not limited thereto. In the present specification and the drawings, components having substantially the same functional configurations are denoted by the same reference numerals, and duplicate descriptions thereof may be omitted. Further, in the following description, an XYZ orthogonal coordinate system is used, but the XYZ coordinate system is defined for the sake of convenience of description and does not limit the orientation of a semiconductor device. Further, when viewed from an arbitrary point, the +Z side may be referred to as “above”, “upper side”, or “upward”, and the −Z side may be referred to as “below”, “lower side”, or “downward”.

### First Embodiment

A first embodiment will be described. The first embodiment relates to a semiconductor device including a GaN-based high electron mobility transistor (HEMT).

### Structure of Semiconductor Device

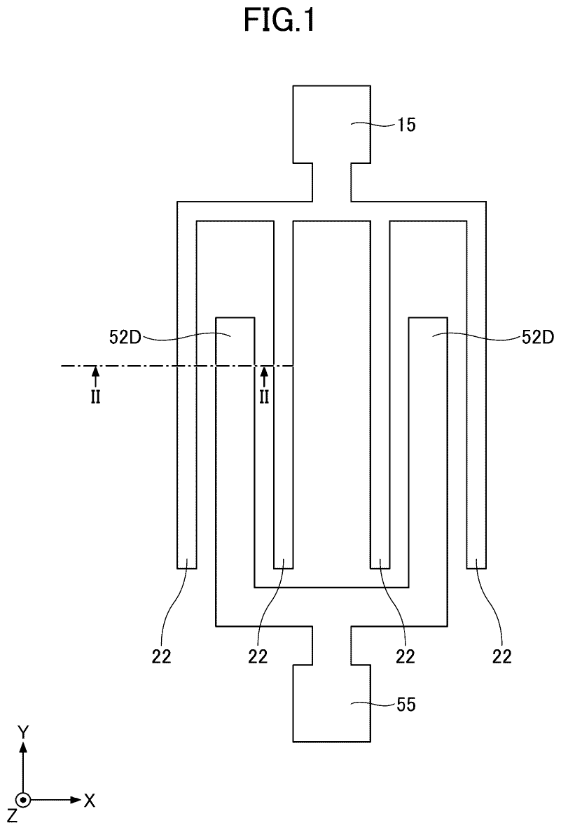

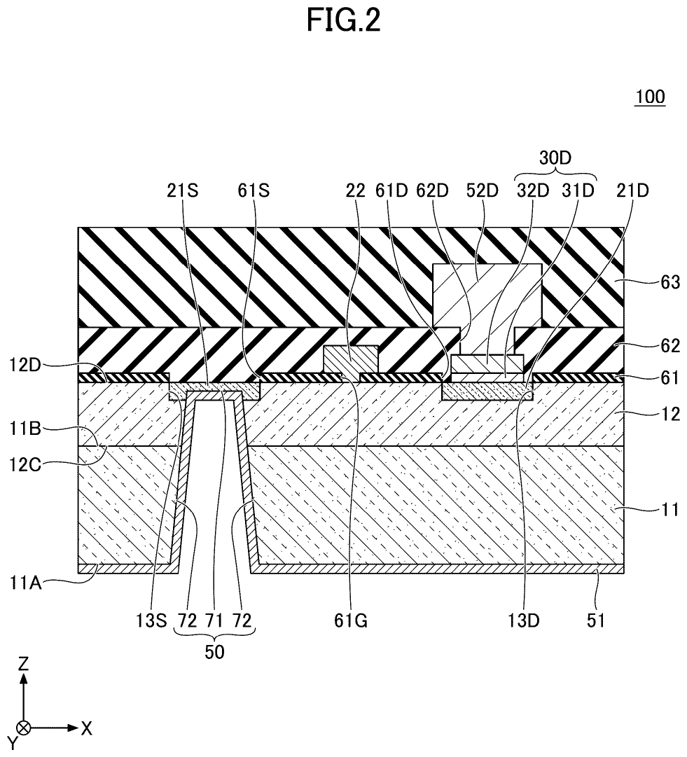

A structure of a semiconductor device according to the first embodiment will be described. FIG. 1 is a diagram illustrating a layout of gate electrodes and drain interconnects of the semiconductor device according to the first embodiment. FIG. 2 is a cross-sectional view illustrating the semiconductor device according to the first embodiment. FIG. 2 corresponds to a cross-sectional view taken along the line II-II of FIG. 1.

As illustrated in FIG. 1 and FIG. 2, a semiconductor device 100 according to the first embodiment includes a substrate 11, a semiconductor layer 12, a semiconductor layer 21S, a semiconductor layer 21D, a gate electrode 22, a drain electrode 30D, a drain interconnect 52D, and a backside electrode 51.

The substrate 11 is, for example, a silicon carbide (SiC) substrate. The substrate 11 has a first surface 11A and a second surface 11B opposite to the first surface 11A. The second surface 11B is located above (on the +Z side of) the first surface 11A.

The semiconductor layer 12 is provided on the substrate 11. The semiconductor layer 12 has a third surface 12C in contact with the second surface 11B, and has a fourth surface 12D opposite to the third surface 12C. The fourth surface 12D is located above (on the +Z side of) the third surface 12C. The semiconductor layer 12 is, for example, a nitride semiconductor layer containing gallium (Ga). The nitride semiconductor layer constitutes a portion of a high electron mobility transistor, such as an electron transport layer (a channel layer) or an electron supply layer (a barrier layer), and includes a two-dimensional electron gas (2DEG). The semiconductor layer 12 is an example of a first nitride semiconductor layer.

A plurality of recesses 13S and a plurality of recesses 13D are formed in the fourth surface 12D. The recesses 13S and 13D extend parallel to the Y-axis, and are alternately provided along the X-axis. For example, the recesses 13S and 13D reach the electron transport layer (the channel layer). The bottom surfaces of the recesses 13S and 13D may be located in the electron transport layer.

The semiconductor device 100 includes an insulating film 61. The insulating film 61 covers the fourth surface 12D of the semiconductor layer 12. For example, the insulating film 61 is a nitride film, such as a silicon nitride (SiN) film. A plurality of openings 61S, a plurality of openings 61D, and a plurality of openings 61G are formed in the insulating film 61. The openings 61S, 61D, and 61G extend parallel to the Y-axis. An opening 61S is continuous with a recess 13S, and an opening 61D is continuous with a recess 13D. An opening 61G is provided between the opening 61S and the opening 61D that are adjacent to each other along the X-axis.

The semiconductor layer 21S is provided in the recess 13S, and the semiconductor layer 21D is provided in the recess 13D. A portion of the semiconductor layer 21S may be inside the opening 61S, and a portion of the semiconductor layer 21D may be inside the opening 61D. For example, the semiconductor layers 21S and 21D are gallium nitride (GaN) layers having an n-type conductivity. The semiconductor layers 21S and 21D are regrown layers. A carrier density of each of the semiconductor layers 21S and 21D is higher than a carrier density of the semiconductor layer 12. The semiconductor layers 21S and 21D contain n-type impurity atoms at a concentration of 1.0×10¹⁸ cm⁻³ or higher. The semiconductor layers 21S and 21D are, for example, degenerate semiconductor layers. The n-type impurity is, for example, silicon (Si) or germanium (Ge). The semiconductor layer 21S is an example of a second nitride semiconductor layer.

The gate electrode 22 extends parallel to the Y-axis. The gate electrode 22 covers the opening 61G of the insulating film 61 and is in Schottky contact with the semiconductor layer 12 through the opening 61G. The gate electrode 22 includes, for example, a nickel (Ni) layer and a gold (Au) layer laminated upward in this order. As illustrated in FIG. 1, a plurality of gate electrodes 22 are connected to a gate common connection part 15.

The drain electrode 30D extends parallel to the Y-axis. The drain electrode 30D includes an Ni layer 31D and an Au layer 32D inside the opening 61D in a plan view. The Ni layer 31D is provided on the semiconductor layer 21D, and the Au layer 32D is provided on the Ni layer 31D. The Ni layer 31D is in direct contact with the semiconductor layer 21D.

The semiconductor device 100 includes an insulating film 62. The insulating film 62 covers the drain electrode 30D, the gate electrode 22, the insulating film 61, the semiconductor layer 21S, and the semiconductor layer 21D. For example, the insulating film 62 is a nitride film, such as a SiN film. A plurality of openings 62D are formed in the insulating film 62. An opening 62D extends parallel to the Y-axis. The opening 62D reaches the drain electrode 30D.

The drain interconnect 52D is located over the drain electrode 30D. The drain interconnect 52D is provided on the insulating film 62. The drain interconnect 52D is in contact with the drain electrode 30D through the opening 62D. The drain interconnect 52D includes, for example, a seed layer and a plating layer on the seed layer. For example, the seed layer includes a titanium (Ti) layer, and the plating layer includes a gold (Au) layer. As illustrated in FIG. 1, a plurality of drain interconnects 52D may be connected to a drain pad 55.

The semiconductor device 100 includes an insulating film 63. The insulating film 63 covers the drain interconnect 52D and the insulating film 62. For example, the insulating film 63 is a nitride film, such as a SiN film.

Although not illustrated, an opening reaching the gate common connection part 15 is formed in the insulating film 62, and a gate pad in contact with the gate common connection part 15 through this opening is formed on the insulating film 62. In addition, an opening reaching the gate pad and an opening reaching the drain pad 55 are formed in the insulating film 63.

An opening 50 penetrating the substrate 11 and the semiconductor layer 12 is formed in the substrate 11 and the semiconductor layer 12. The opening 50 reaches the semiconductor layer 21S. The opening 50 has a bottom surface 71 and an inner wall surface 72. The inner wall surface 72 is continuous with the lower surface (first surface 11A) of the substrate 11, and the bottom surface 71 is continuous with the inner wall surface 72. The bottom surface 71 is located in the semiconductor layer 21S. The opening 50 may enter the semiconductor layer 21S. At least one opening 50 is formed for each semiconductor layer 21S. A plurality of openings 50 may be formed for each semiconductor layer 21S.

The backside electrode 51 is formed on the lower surface of the semiconductor layer 21S, the inner wall surface 72 of the opening 50, and the lower surface (first surface 11A) of the substrate 11. The backside electrode 51 covers the first surface 11A and the inner wall surface 72, and is in contact with the semiconductor layer 21S at the bottom surface 71. The backside electrode 51 includes, for example, a seed layer and a plating layer. For example, the seed layer includes a titanium (Ti) layer, a nickel (Ni) layer, a nickel-chromium (NiCr) alloy layer, or a tantalum (Ta) layer, and the plating layer includes a gold (Au) layer. The backside electrode 51 is an example of a first metal layer.

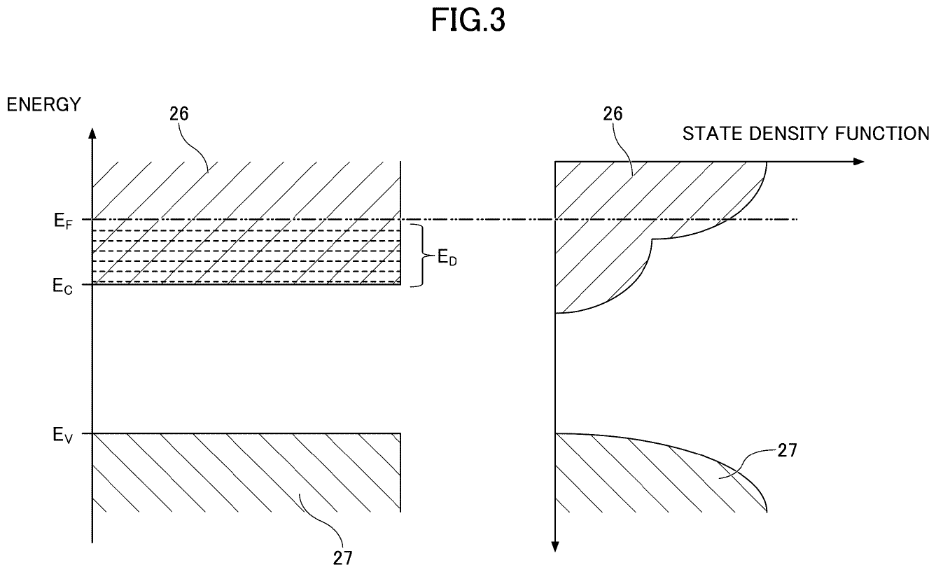

In the semiconductor device 100, the semiconductor layer 21S is formed in the recess 13S of the semiconductor layer 12, and the semiconductor layer 21S contains impurity atoms at a concentration of 1.0×10¹⁸ cm⁻³ or higher. In this semiconductor layer 21S, the distance between the impurity atoms is short, and as illustrated in FIG. 3, a binding band in which the impurity levels (E_{D}) interact with each other is formed, and the binding band is connected to a conduction band 26. At this time, because the Fermi level (E_{F}) is present in the conduction band, that is, the Fermi level (E_{F}) is higher than energy (E_{c}) at the bottom of the conduction band, the semiconductor layer 21S exhibits properties similar to properties of metal. That is, the semiconductor layer 21S functions as a degenerate semiconductor layer. Accordingly, an ohmic contact is obtained between the semiconductor layer 21S and the backside electrode 51. FIG. 3 is a diagram illustrating a band structure of the semiconductor layer 21S. In FIG. 3, E_{V} indicates energy at the top of a valence band 27.

### First Example of Method for Manufacturing Semiconductor Device

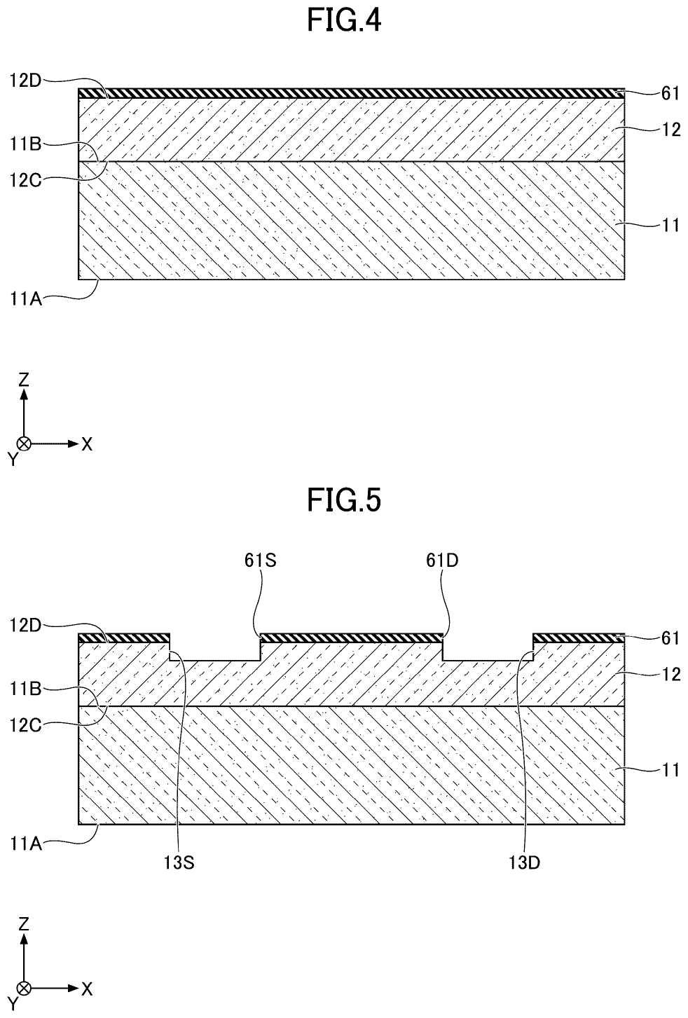

Next, a first example of a method of manufacturing the semiconductor device 100 according to the first embodiment will be described. FIG. 4 to FIG. 13 are cross-sectional views illustrating the first example of the method of manufacturing the semiconductor device 100 according to the first embodiment.

In the first example, as illustrated in FIG. 4, the semiconductor layer 12 is formed on the substrate 11 by, for example, a metal organic chemical vapor deposition (MOCVD) method. The substrate 11 has the first surface 11A and the second surface 11B opposite to the first surface 11A. The semiconductor layer 12 has the third surface 12C in contact with the second surface 11B and the fourth surface 12D opposite to the third surface 12C. Next, the insulating film 61 is formed on the semiconductor layer 12. The insulating film 61 can be formed by, for example, a plasma CVD method. The insulating film 61 covers the fourth surface 12D of the semiconductor layer 12.

Next, as illustrated in FIG. 5, the openings 61S and 61D are formed in the insulating film 61, and the recesses 13S and 13D are formed in the semiconductor layer 12. In the formation of the openings 61S and 61D, for example, reactive ion etching (RIE) of the insulating film 61 is performed using a resist pattern as a mask. When the RIE of the insulating film 61 is performed, a reactive gas containing fluorine (F) is used, for example. In the formation of the recesses 13S and 13D, RIE of the semiconductor layer 12 is performed using the resist pattern used in the formation of the openings 61S and 61D as a mask. When the RIE of the semiconductor layer 12 is performed, a reactive gas containing chlorine (Cl) is used, for example.

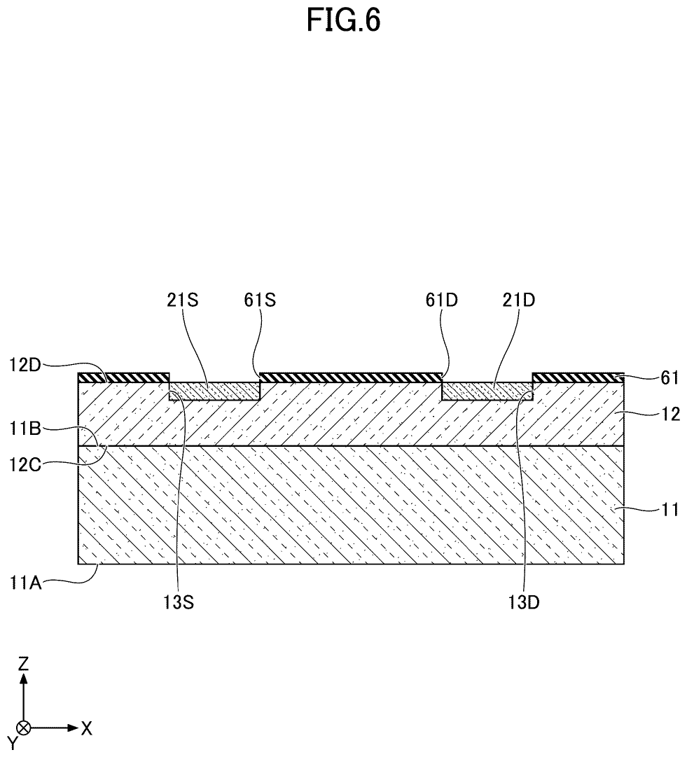

Next, as illustrated in FIG. 6, the semiconductor layer 21S is formed in the recess 13S, and the semiconductor layer 21D is formed in the recess 13D. In the formation of the semiconductor layers 21S and 21D, crystal growth of the semiconductor layers is performed by, for example, a MOCVD method, a molecular beam epitaxy (MBE) method, or a sputtering method using a growth mask, and then the growth mask is removed. The semiconductor layers 21S and 21D are what are known as regrown layers.

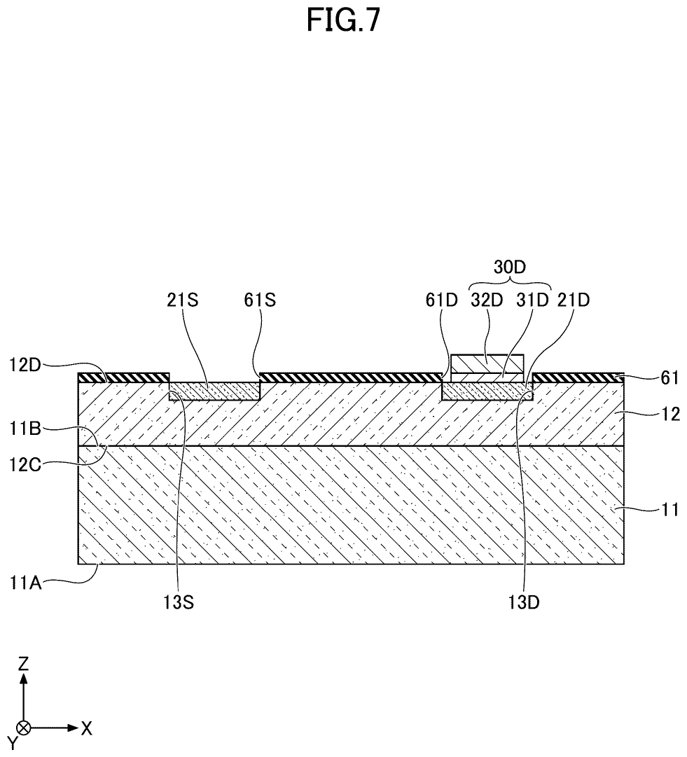

Next, as illustrated in FIG. 7, the drain electrode 30D is formed on the semiconductor layer 21D. In the formation of the drain electrode 30D, an Ni layer and an Au layer are grown by a vapor deposition method using a growth mask, and then the growth mask is removed. That is, the drain electrode 30D can be formed by, for example, vapor deposition and lift-off.

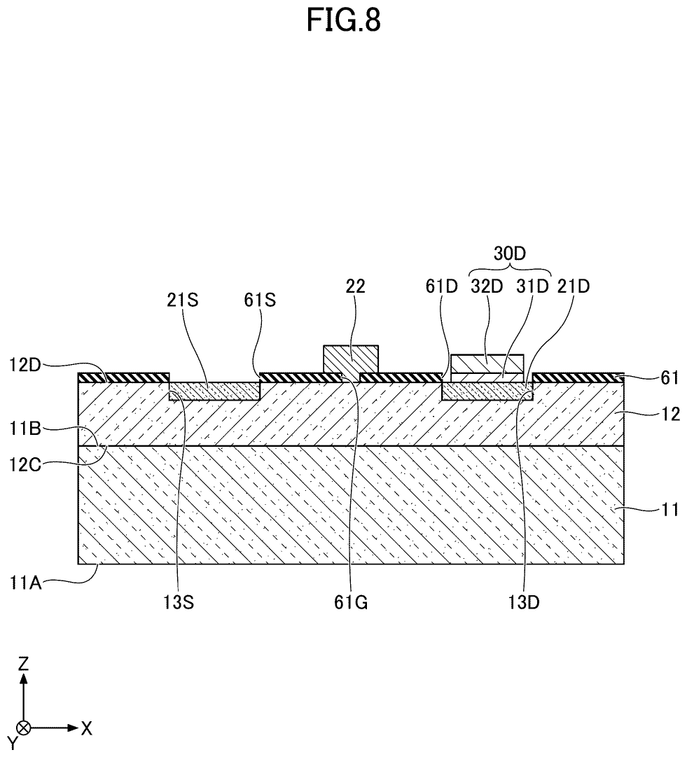

Next, as illustrated in FIG. 8, the opening 61G is formed in the insulating film 61. In the formation of the opening 61G, for example, RIE using a resist pattern as a mask is performed. A reactive gas containing F is used to etch the insulating film 61, for example. Next, the gate electrode 22 is formed on the insulating film 61. In the formation of the gate electrode 22, an Ni layer and an Au layer are grown by a vapor deposition method using a growth mask, and then the growth mask is removed. That is, the gate electrode 22 can be formed by, for example, vapor deposition and lift-off. The gate electrode 22 is in Schottky contact with the semiconductor layer 12 through the opening 61G.

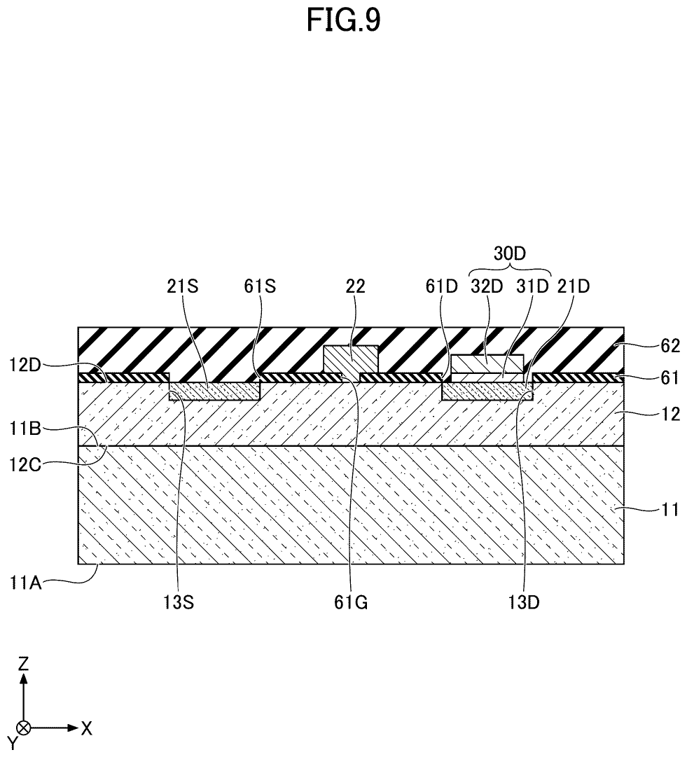

Next, as illustrated in FIG. 9, the insulating film 62 is formed on the drain electrode 30D, the gate electrode 22, the insulating film 61, the semiconductor layer 21S, and the semiconductor layer 21D. The insulating film 62 can be formed by, for example, a plasma CVD method. The insulating film 62 covers the drain electrode 30D, the gate electrode 22, the insulating film 61, the semiconductor layer 21S, and the semiconductor layer 21D.

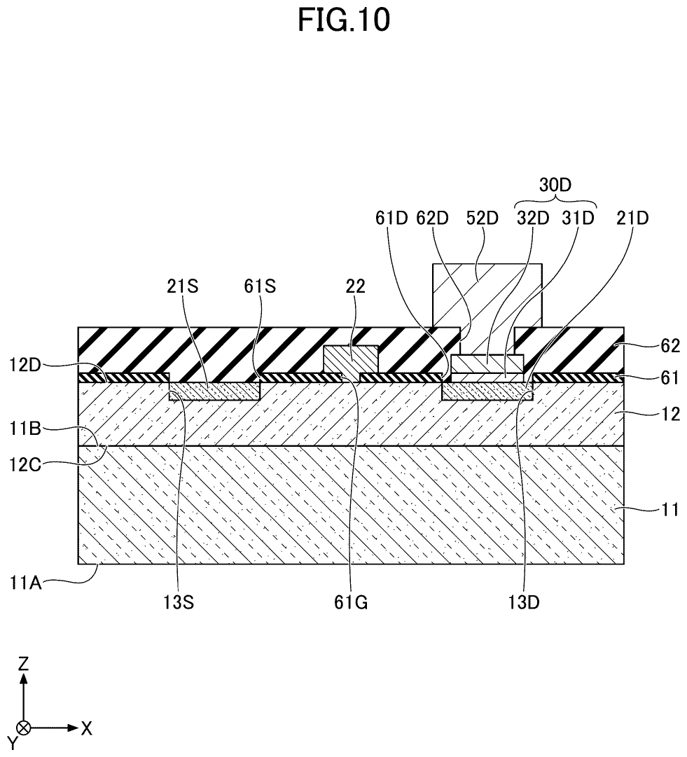

Next, as illustrated in FIG. 10, the opening 62D is formed in the insulating film 62. In the formation of the opening 62D, RIE of the insulating film 62 is performed using a resist pattern as a mask, for example. When the RIE of the insulating film 62 is performed, a reactive gas containing F is used, for example. Next, the drain interconnect 52D is formed on the insulating film 62 so as to be in contact with the drain electrode 30D through the opening 62D.

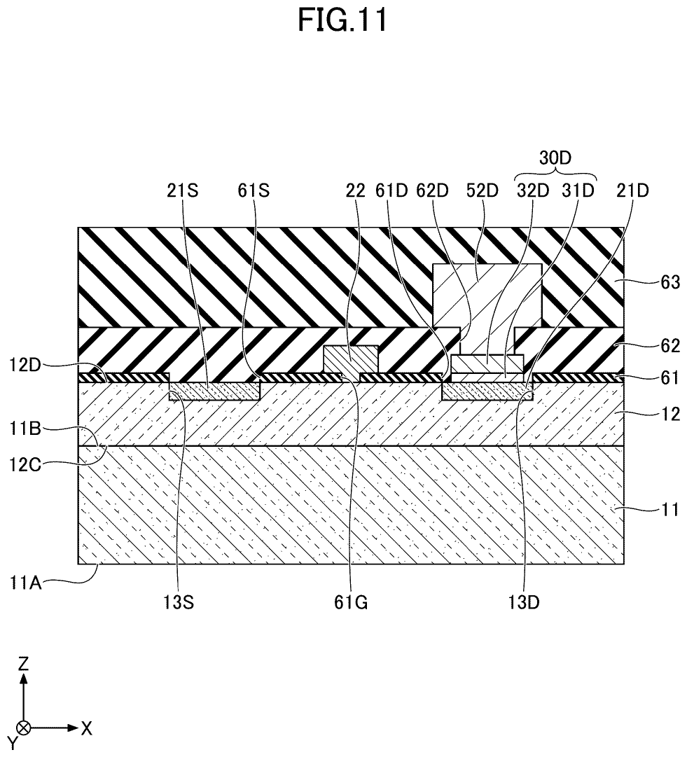

Next, as illustrated in FIG. 11, the insulating film 63 is formed on the insulating film 62. The insulating film 63 can be formed by, for example, a plasma CVD method. The insulating film 63 covers the drain interconnect 52D and the insulating film 62.

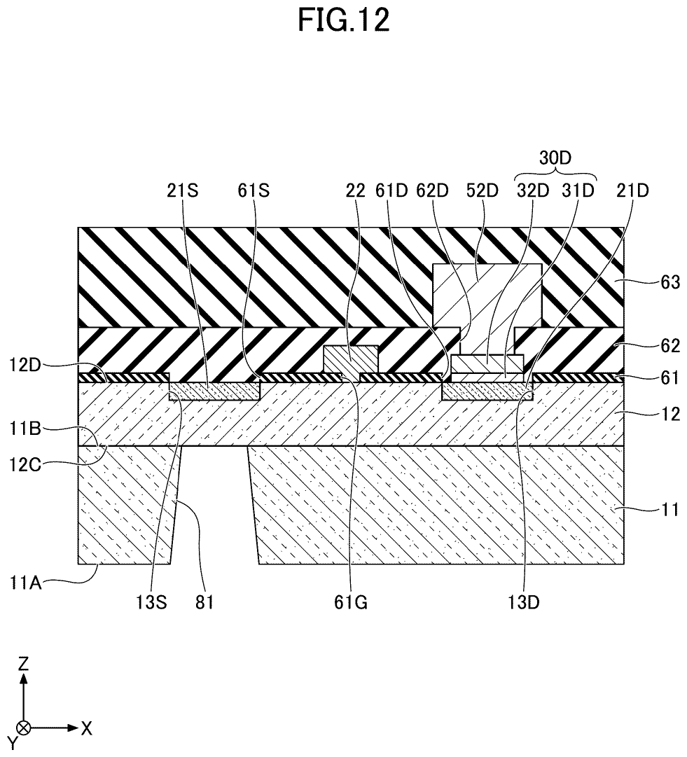

Next, as illustrated in FIG. 12, an opening 81 penetrating the substrate 11 is formed in the substrate 11. The opening 81 is formed so as to reach the semiconductor layer 12. The lower surface of the semiconductor layer 12 is exposed in the opening 81. In the formation of the opening 81, RIE of the substrate 11 is performed, for example. When the RIE of the substrate 11 is performed, a reactive gas containing F is used, for example. When the RIE of the substrate 11 is performed so as to form the opening 81, a mask is formed on the first surface 11A, and the mask is removed after the substrate 11 is etched.

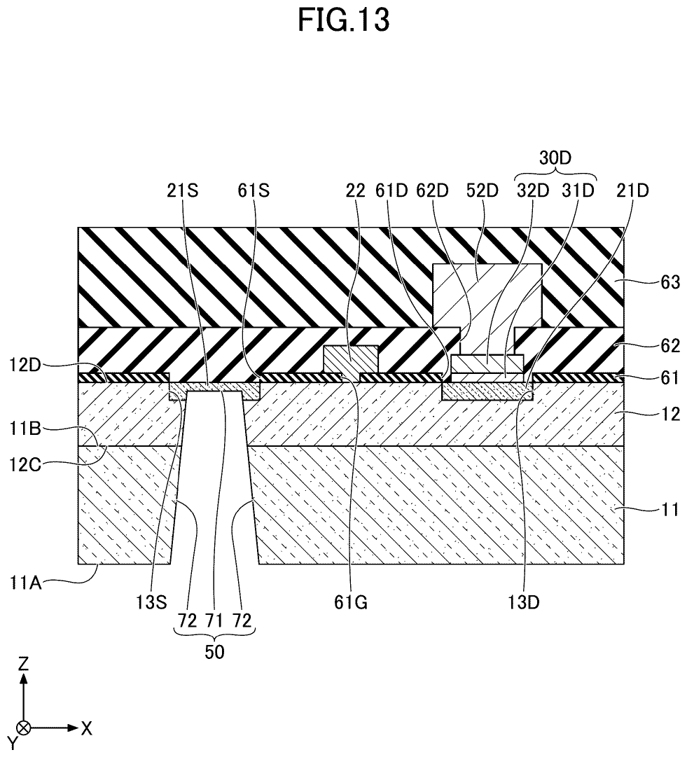

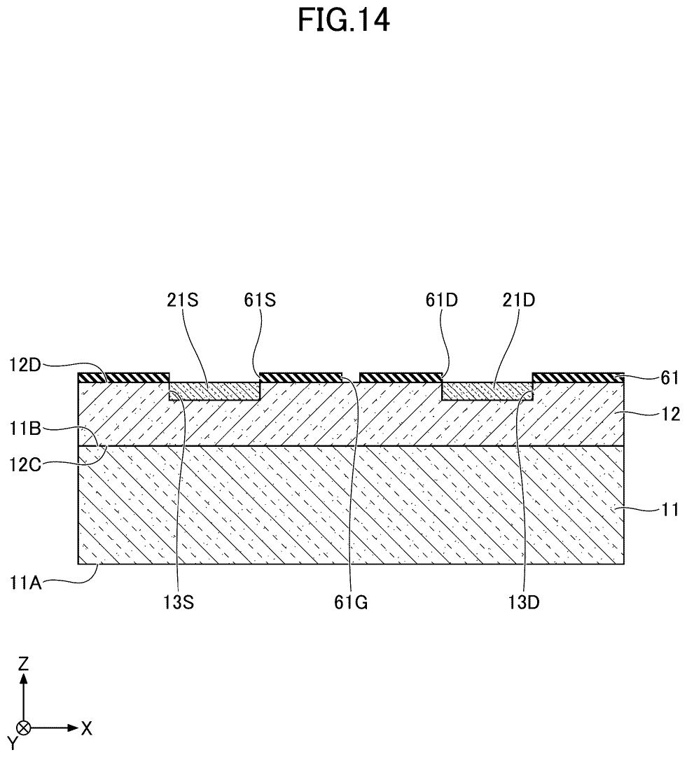

Next, as illustrated in FIG. 13, RIE of the semiconductor layer 12 and the semiconductor layer 21S is performed through the opening 81, and the opening 50 penetrating the substrate 11 and the semiconductor layer 12 is formed in the substrate 11 and the semiconductor layer 12. The opening 50 includes the opening 81. The opening 50 is formed so as to reach the semiconductor layer 21S. The opening 50 has the bottom surface 71 and the inner wall surface 72. The inner wall surface 72 is continuous with the lower surface (first surface 11A) of the substrate 11, and the bottom surface 71 is continuous with the inner wall surface 72. The bottom surface 71 is located in the semiconductor layer 21S. The opening 50 may enter the semiconductor layer 21S. When the RIE of the semiconductor layer 12 and the semiconductor layer 21S is performed, a reactive gas containing Cl is used, for example. The RIE of the semiconductor layer 12 and the semiconductor layer 21S is stopped before the opening 50 penetrates the semiconductor layer 21S based on, for example, time control. After the opening 50 is formed, the inside of the opening 50 is cleaned.

Next, the backside electrode 51 is formed (see FIG. 2). The backside electrode 51 covers the first surface 11A and the inner wall surface 72, and is in contact with the semiconductor layer 21S at the bottom surface 71. In the formation of the backside electrode 51, for example, a seed layer is formed by a sputtering method, and then a plating layer is formed on the seed layer.

In this manner, the semiconductor device 100 according to the first embodiment can be manufactured.

### Second Example of Method of Manufacturing Semiconductor Device

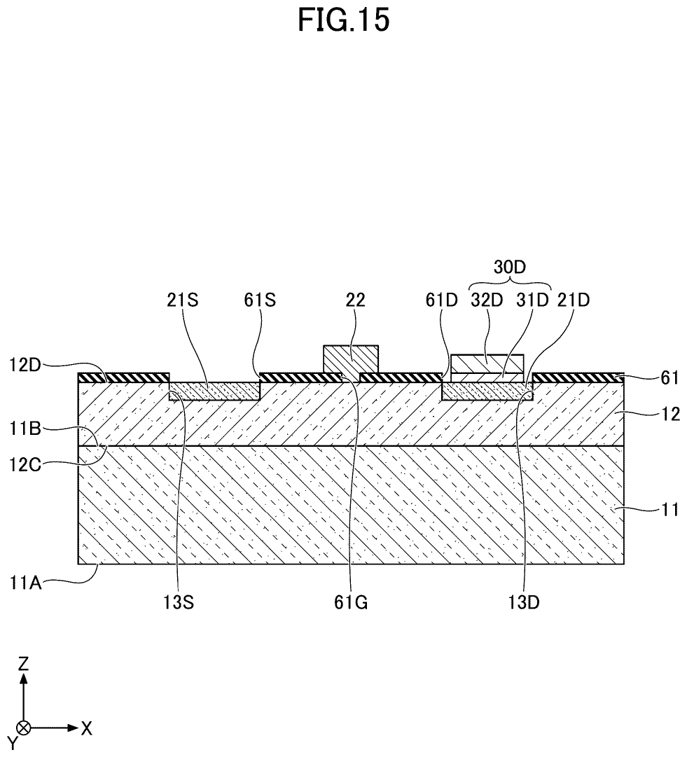

Next, a second example of the method of manufacturing the semiconductor device 100 according to the embodiment will be described. FIG. 14 and FIG. 15 are cross-sectional views illustrating the second example of the method of manufacturing the semiconductor device 100 according to the first embodiment.

In the second example, the processes up to the formation of the semiconductor layer 21S and 21D are performed in the same manner as in the first example (see FIG. 4 to FIG. 6). Next, as illustrated in FIG. 14, the opening 61G is formed in the insulating film 61.

Next, as illustrated in FIG. 15, the drain electrode 30D is formed on the semiconductor layer 21D, and the gate electrode 22 is formed on the insulating film 61. In the formation of each of the drain electrode 30D and the gate electrode 22, an Ni layer and an Au layer are grown by a vapor deposition method using a growth mask, and then the growth mask is removed. The drain electrode 30D and the gate electrode 22 may be formed simultaneously.

Thereafter, the process of forming the insulating film 62 and the subsequent processes are performed in the same manner as in the first example (see FIG. 9 to FIG. 13 and FIG. 2).

In this manner, the semiconductor device 100 according to the first embodiment can be manufactured.

In the first embodiment, in both the first example and the second example, the mask used for the RIE of the substrate 11 may be removed after the opening 50 is formed. Alternatively, the opening 50 may be formed by continuously performing the RIE of the substrate 11 and the RIE of the semiconductor layer 12 using a reactive gas containing F, and then the mask may be removed.

In the semiconductor device 100, the backside electrode 51 is in contact with the semiconductor layer 21S at the bottom surface 71 of the opening 50, and the backside electrode 51 and the semiconductor layer 21S are in ohmic contact with each other. For this reason, the electrical resistance between the semiconductor layer 12 including the 2DEG and the backside electrode 51 is low. Although a crystal defect may be present in the semiconductor layer 21S, an increase in the electrical resistance between the backside electrode 51 and the semiconductor layer 21S due to such a crystal defect is small. Therefore, according to the semiconductor device 100, the stability of the electrical resistance between the backside electrode 51 and the semiconductor layer 12 is good, and thus yield can be improved.

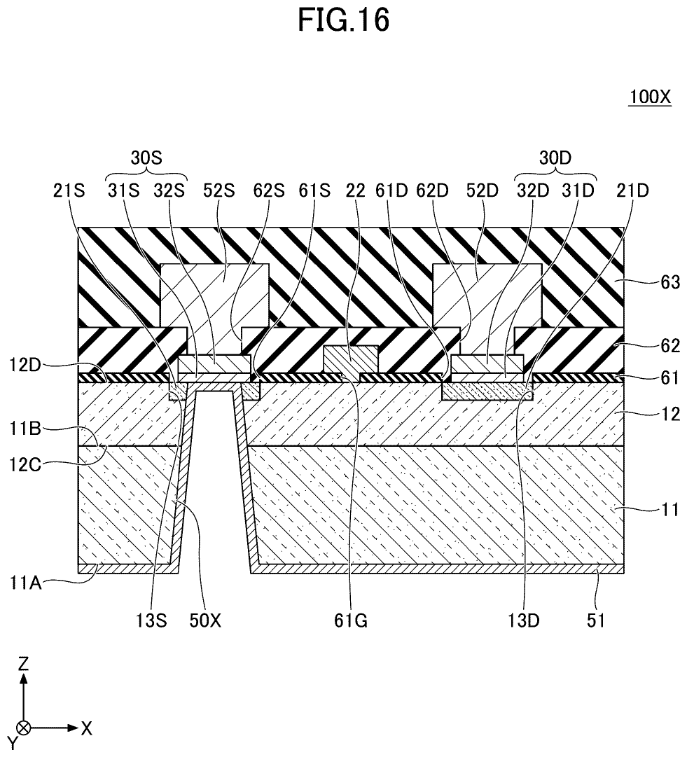

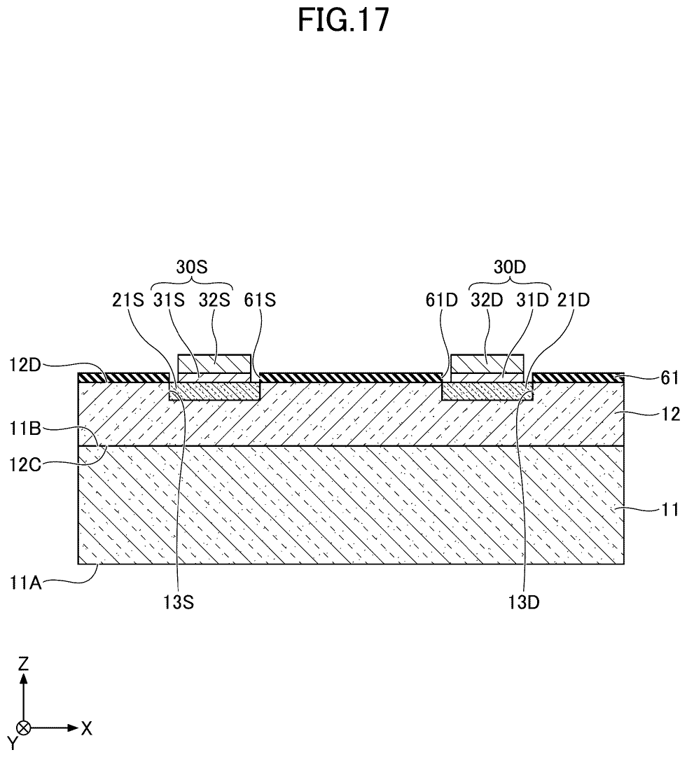

Herein, the electrical resistance between the backside electrode 51 and the semiconductor layer 12 will be further described in comparison with a reference example. FIG. 16 is a cross-sectional view illustrating a semiconductor device according to the reference example. FIG. 17 to FIG. 23 are cross-sectional views illustrating a method of manufacturing the semiconductor device according to the reference example.

As illustrated in FIG. 16, a semiconductor device 100X according to the reference example includes a source electrode 30S and a source interconnect 52S. The source electrode 30S includes an Ni layer 31S and an Au layer 32S inside an opening 61S in a plan view. The Ni layer 31S is provided on a semiconductor layer 21S, and the Au layer 32S is provided on the Ni layer 31S. The Ni layer 31S is in direct contact with the semiconductor layer 21S. An insulating film 62 covers the source electrode 30S, and a plurality of openings 62S are formed in the insulating film 62. An opening 62S reaches the source electrode 30S.

The source interconnect 52S is located over the source electrode 30S. The source interconnect 52S is provided on the insulating film 62. The source interconnect 52S is in contact with the source electrode 30S through the opening 62S. An insulating film 63 covers the source interconnect 52S.

Instead of the opening 50, a through hole 50X penetrating a substrate 11, a semiconductor layer 12, and the semiconductor layer 21S is formed in the substrate 11, the semiconductor layer 12, and the semiconductor layer 21S. The through hole 50X reaches the source electrode 30S. A backside electrode 51 is formed on a lower surface of the source electrode 30S, an inner wall surface of the through hole 50X, and a lower surface (first surface 11A) of the substrate 11. The backside electrode 51 is in contact with the source electrode 30S and covers the first surface 11A and the inner wall surface of the through hole 50X. The backside electrode 51 and the source electrode 30S are electrically connected to each other, and the source electrode 30S and the semiconductor layer 21S are in ohmic contact with each other.

The other configurations of the semiconductor device 100X are the same as those of the semiconductor device 100.

In a method of manufacturing the semiconductor device 100X, the processes up to the formation of the semiconductor layer 21S and a semiconductor layer 21D are performed in the same manner as in the first example (see FIG. 4 to FIG. 6). Next, as illustrated in FIG. 17, the source electrode 30S is formed simultaneously when a drain electrode 30D is formed.

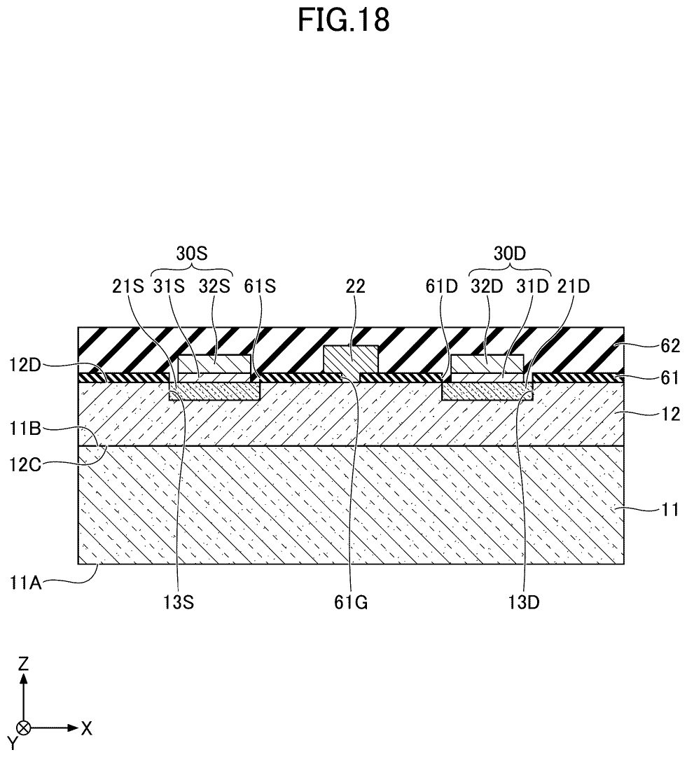

Next, as illustrated in FIG. 18, the processes up to the formation of an opening 61G to the formation of the insulating film 62 are performed in the same manner as in the first example.

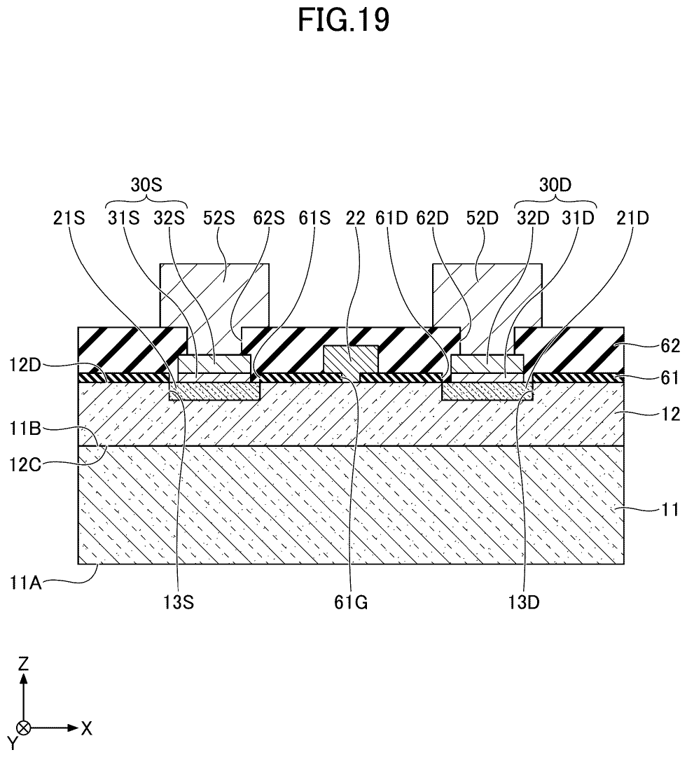

Next, as illustrated in FIG. 19, the opening 62S is formed simultaneously when an opening 62D is formed, and the source interconnect 52S is formed simultaneously when a drain interconnect 52D is formed.

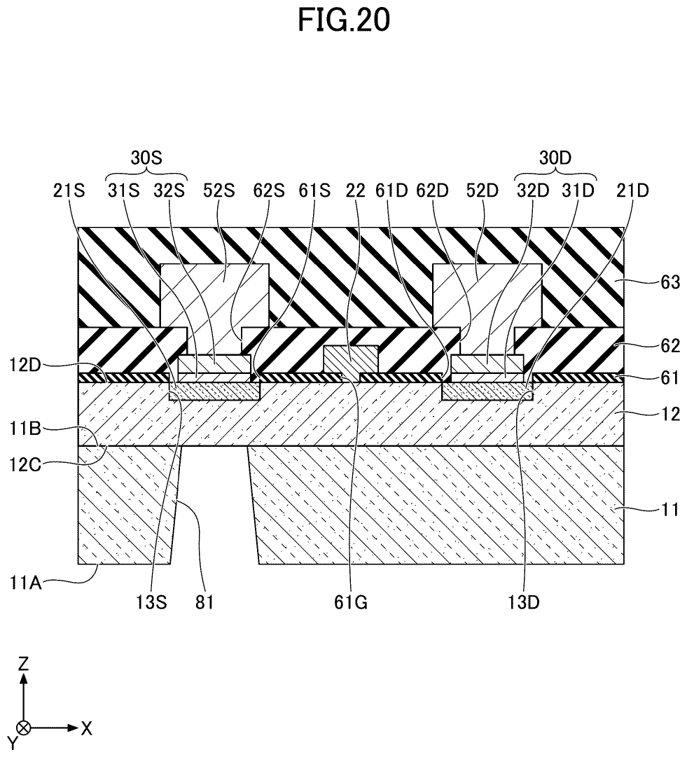

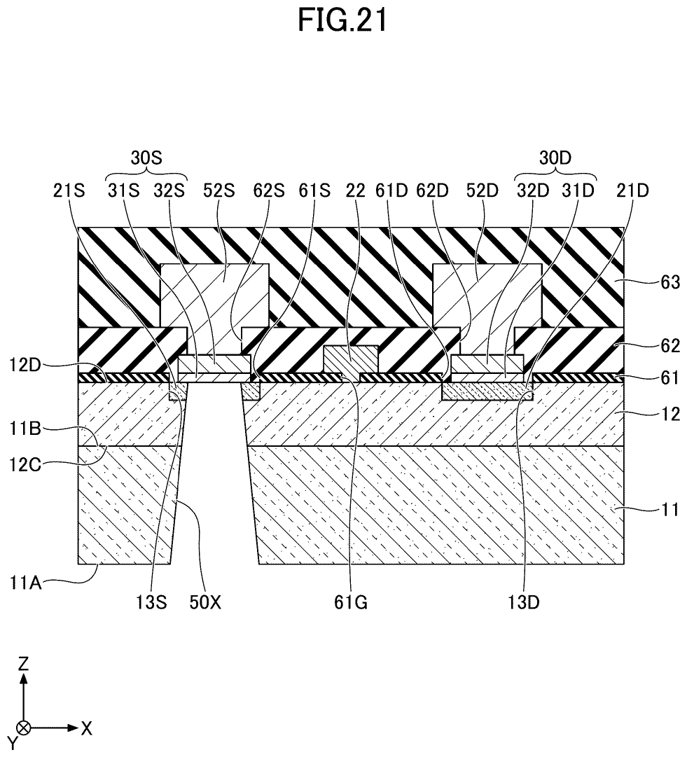

Next, as illustrated in FIG. 20, the processes up to the formation of the insulating film 63 to the formation of an opening 81 are performed in the same manner as in the first example. Next, as illustrated in FIG. 21, RIE of the semiconductor layer 12 and the semiconductor layer 21S is performed through the opening 81, and the through hole 50X penetrating the substrate 11, the semiconductor layer 12, and the semiconductor layer 21S is formed in the substrate 11, the semiconductor layer 12, and the semiconductor layer 21S. In the formation of the through hole 50X, the source electrode 30S is used as an etching stopper, and through hole 50X is formed so as to reach the source electrode 30S. The through hole 50X may enter the source electrode 30S. When the RIE of the semiconductor layer 12 and the semiconductor layer 21S is performed, a reactive gas containing Cl is used, for example. After the through hole 50X is formed, the inside of the through hole 50X is cleaned.

Next, the backside electrode 51 is formed (see FIG. 16). In this manner, the semiconductor device 100X according to the reference example can be manufactured.

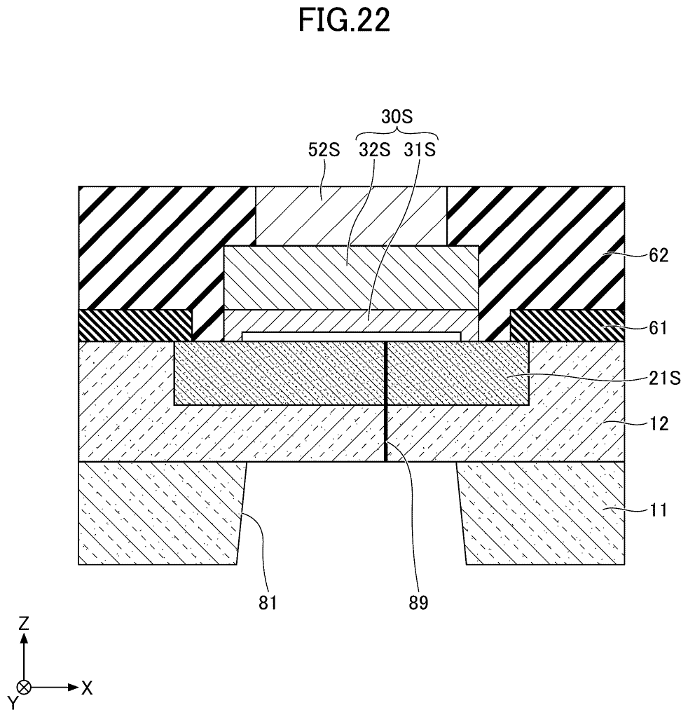

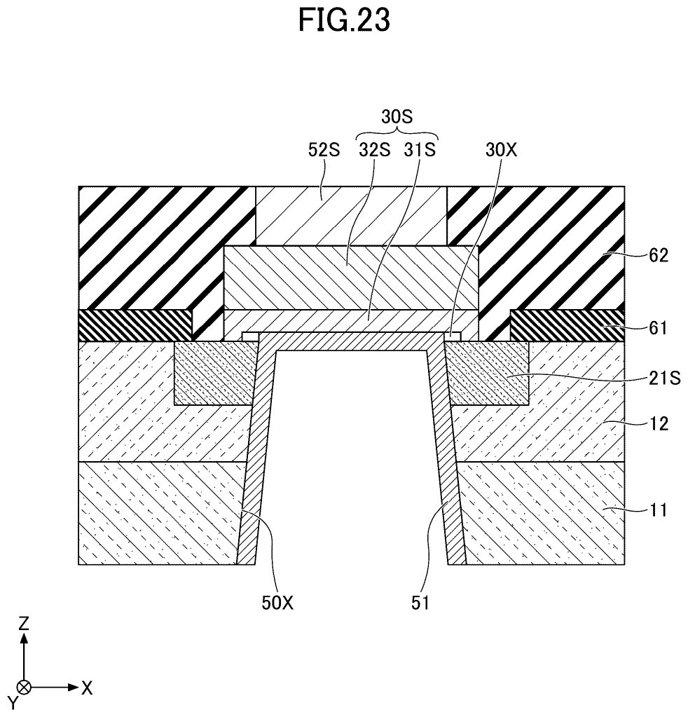

In the semiconductor device 100X, the through hole 50X reaches the source electrode 30S, and the source electrode 30S and the semiconductor layer 21S are in ohmic contact with each other. However, as illustrated in FIG. 22, if a crystal defect 89 is present in the semiconductor layer 12 and the semiconductor layer 21S, when a mask used for the RIE of the substrate 11 is removed, a substance used to remove the mask may reach the source electrode 30S through the crystal defect 89, thereby resulting in a partial loss of the source electrode 30S. A partial loss of the source electrode 30S may also occur when the inside of the through hole 50X is cleaned after the through hole 50X is formed. For this reason, as illustrated in FIG. 23, after the formation of the backside electrode 51, a gap 30X may be present between the source electrode 30S and the semiconductor layer 21S. If the gap 30X is present, the contact resistance between the source electrode 30S and the semiconductor layer 21S would be increased and yield would be reduced. In contrast, in the semiconductor device 100, the backside electrode 51 is in contact with the semiconductor layer 21S at the bottom surface 71 of the opening 50, and the backside electrode 51 and the semiconductor layer 21S are in ohmic contact with each other. Accordingly, unlike the reference example, even if the crystal defect 89 is present, an increase in the contact resistance does not occur, and yield can be improved.

In the semiconductor device 100X, the backside electrode 51 may be in contact with the semiconductor layer 21S at the inner wall surface of the through hole 50X, but the contact area is extremely small. Further, an etching residue generated during the etching of the semiconductor layer 12 and the semiconductor layer 21S is likely to be present on the inner wall surface of the through hole 50X. Therefore, even if the backside electrode 51 is in contact with the semiconductor layer 21S at the inner wall surface of the through hole 50X, this contact is less likely to contribute to a reduction in the contact resistance. In the semiconductor device 100 as well, even if the backside electrode 51 is in contact with the semiconductor layer 21S at the inner wall surface 72 of the opening 50, this contact is less likely to contribute to a reduction in the contact resistance. However, in the semiconductor device 100, because the backside electrode 51 is in contact with the semiconductor layer 21S at the bottom surface 71 of the opening 50, the contact resistance can be reduced.

The thickness of the semiconductor layer 21S is, for example, 20 nm or more and 1,000 nm or less, and may be 150 nm or more and 400 nm or less. When the thickness of the semiconductor layer 21S is 20 nm or more, the RIE of the semiconductor layer 12 and the semiconductor layer 21S is easily stopped before the opening 50 penetrates the semiconductor layer 21S. When the thickness of the semiconductor layer 21S is 150 nm or more, the RIE of the semiconductor layer 12 and the semiconductor layer 21S is more easily stopped before the opening 50 penetrates the semiconductor layer 21S. When the thickness of the semiconductor layer 21S is 1,000 nm or less, the time required for the formation of the recess 13S and the formation of the semiconductor layer 21S is easily reduced. When the thickness of the semiconductor layer 21S is 400 nm or less, the time required for the formation of the recess 13S and the formation of the semiconductor layer 21S is more easily reduced. The thickness of the semiconductor layer 21S can be measured by using a transmission electron microscope (TEM) or a cross-sectional scanning electron microscope (SEM).

When the semiconductor layer 21S is a GaN layer, a low electrical resistance is easily obtained for the semiconductor layer 21S.

The carrier density of each of the semiconductor layers 21S and 21D is higher than the carrier density of the semiconductor layer 12. Thus, the electrical resistance of the semiconductor device 100 is easily reduced. Specifically, the electrical resistance between the backside electrode 51 and the drain interconnect 52D is easily reduced.

The semiconductor layer 21S may contain n-type impurity atoms at a concentration of 1.0×10¹⁹ cm⁻³ or higher, or may contain n-type impurity atoms at a concentration of 1.0×10²⁰ cm⁻³ or higher. The higher the concentration of the n-type impurity atoms in the semiconductor layer 21S, the easier it is to obtain an ohmic contact with the backside electrode 51.

Similarly, the semiconductor layer 21D may contain n-type impurity atoms at a concentration of 1.0×10¹⁹ cm⁻³ or higher, or may contain n-type impurity atoms at a concentration of 1.0×10²⁰ cm⁻³ or higher. The higher the concentration of the n-type impurity atoms in the semiconductor layer 21D, the easier it is to obtain an ohmic contact with the drain electrode 30D. The concentration of the impurity atoms can be measured by secondary ion mass spectrometry (SIMS).

### Second Embodiment

A second embodiment will be described. The second embodiment differs from the first embodiment mainly in that a source electrode and a source interconnect are included.

### Structure of Semiconductor Device

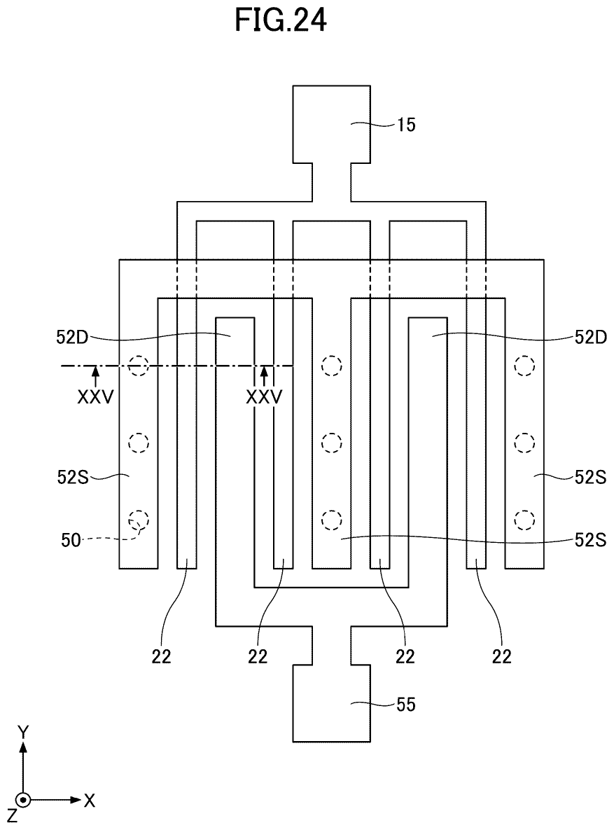

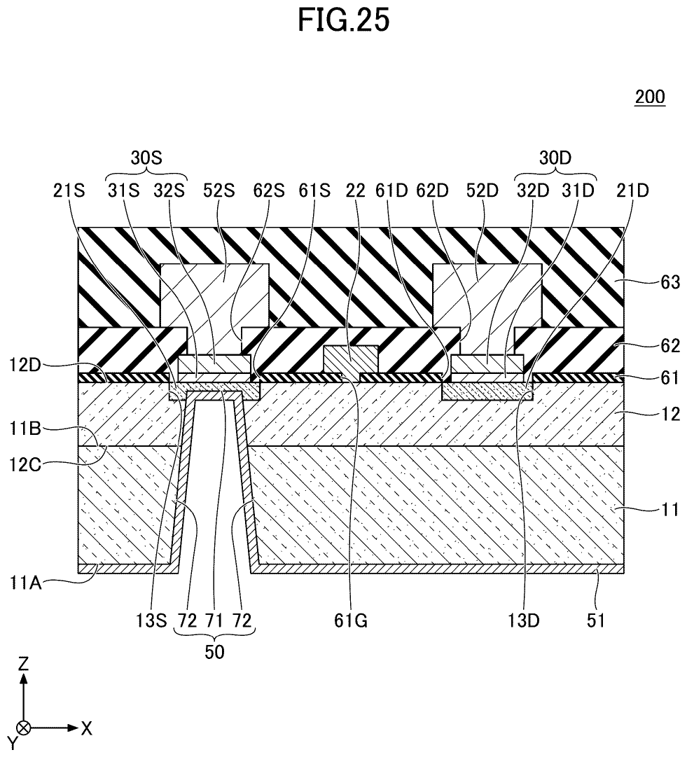

A structure of a semiconductor device according to the second embodiment will be described. FIG. 24 is a diagram illustrating a layout of gate electrodes, source interconnects, and drain interconnects of the semiconductor device according to the second embodiment. FIG. 25 is a cross-sectional view illustrating the semiconductor device according to the second embodiment. FIG. 25 corresponds to a cross-sectional view taken along the line XXV-XXV of FIG. 24.

As illustrated in FIG. 24 and FIG. 25, a semiconductor device 200 according to the second embodiment includes, a source electrode 30S and a source interconnect 52S in addition to the configuration of the semiconductor device 100. A plurality of source interconnect 52S may be connected to each other. The configurations of the source electrode 30S, the insulating film 62, and the source interconnect 52S are the same as those of the semiconductor device 100X according to the reference example. The source electrode 30S is an example of a second metal layer.

The other configurations of the semiconductor device 200 are the same as those of the semiconductor device 100.

### Method of Manufacturing Semiconductor Device

When the semiconductor device 200 according to the second embodiment is manufactured, the source electrode 30S and the source interconnect 52S are formed in the same manner as in the reference example. Further, the opening 81 and the opening 50 are formed in the same manner as in the first embodiment. In this manner, the semiconductor device 200 according to the second embodiment can be manufactured.

Similar to the first embodiment, in the second embodiment, yield can be improved. As in the reference example, although a partial loss of the source electrode 30S may occur, such a partial loss of the source electrode 30S does not affect the contact resistance. This is because the backside electrode 51 is in contact with the semiconductor layer 21S at the bottom surface 71 of the opening 50, and the backside electrode 51 and the semiconductor layer 21S are in ohmic contact with each other.

Further, in the semiconductor device 200 according to the second embodiment, the source interconnect 52S can be used to perform a characteristic inspection. For example, the characteristic inspection can be performed before the backside electrode 51 is formed.

Although embodiments have been described in detail, the present disclosure is not limited to the specific embodiments, and various modifications and changes can be made within the scope described in the claims.

What is claimed is:

1. A semiconductor device comprising:
a substrate having a first surface and a second surface opposite to the first surface;
a first nitride semiconductor layer having a third surface in contact with the second surface, and a fourth surface opposite to the third surface, the first nitride semiconductor layer having a recess formed in the fourth surface;
a second nitride semiconductor layer provided in the recess; and
a first metal layer, wherein
an opening is formed in the substrate and the first nitride semiconductor layer, the opening penetrating the substrate and the first nitride semiconductor layer, reaching the second nitride semiconductor layer, and having a bottom surface in the second nitride semiconductor layer,
the first metal layer covers the first surface and an inner wall surface of the opening, and is in contact with the second nitride semiconductor layer at the bottom surface of the opening, and
the second nitride semiconductor layer contains impurity atoms at a concentration of 1.0×10¹⁸ cm⁻³ or higher.

2. The semiconductor device according to claim 1, wherein a thickness of the second nitride semiconductor layer is 20 nm or more and 1,000 nm or less.

3. The semiconductor device according to claim 1, wherein the second nitride semiconductor layer is a gallium nitride layer.

4. The semiconductor device according to claim 1, wherein a Fermi level is higher than energy at a bottom of a conduction band in the second nitride semiconductor layer.

5. The semiconductor device according to claim 1, wherein a carrier density of the second nitride semiconductor layer is higher than a carrier density of the first nitride semiconductor layer.

6. The semiconductor device according to claim 1, further comprising:
a second metal layer provided on the second nitride semiconductor layer, wherein
the second nitride semiconductor layer is located between the first metal layer and the second metal layer.

7. A method of manufacturing a semiconductor device, the method comprising:
forming a first nitride semiconductor layer on a substrate having a first surface and a second surface opposite to the first surface, the first nitride semiconductor layer having a third surface in contact with the second surface, and a fourth surface opposite to the third surface;
forming a recess in the fourth surface of the first nitride semiconductor layer;
forming a second nitride semiconductor layer in the recess;
forming an opening in the substrate and the first nitride semiconductor layer, the opening penetrating the substrate and the first nitride semiconductor layer, reaching the second nitride semiconductor layer, and having a bottom surface in the second nitride semiconductor layer; and
forming a first metal layer covering the first surface and an inner wall surface of the opening, and being in contact with the second nitride semiconductor layer at the bottom surface of the opening, wherein
the second nitride semiconductor layer contains impurity atoms at a concentration of 1.0×10¹⁸ cm⁻³ or higher.

8. A semiconductor device comprising:
a substrate having a first surface and a second surface opposite to the first surface;
a first nitride semiconductor layer having a third surface in contact with the second surface, and a fourth surface opposite to the third surface, the first nitride semiconductor layer having a recess formed in the fourth surface;
a second nitride semiconductor layer provided in the recess; and
a first metal layer, wherein
a through hole is formed in the substrate and the first nitride semiconductor layer, the through hole penetrating the substrate and the first nitride semiconductor layer, reaching the second nitride semiconductor layer, and having a bottom surface in the second nitride semiconductor layer,
the first metal layer covers the first surface and an inner wall surface of the through hole, and is in contact with the second nitride semiconductor layer at the bottom surface of the through hole, and
the second nitride semiconductor layer contains impurity atoms at a concentration of 1.0×1018 cm−3 or higher.
